(19) United States
(12) Patent Application Publication
(10) Pub. No.: US 2025/0247962 A1
(43) Pub. Date: Jul. 31, 2025

(54) PRINTED CIRCUIT BOARD AND ELECTRONIC DEVICE INCLUDING THE SAME

(71) Applicant: Samsung Electronics Co., Ltd., Suwon-si (KR)

(72) Inventors: Jungwoo YANG, Suwon-si (KR); Junyoung KO, Suwon-si (KR); Moonyoung KIM, Suwon-si (KR); Taeyoon KIM, Suwon-si (KR); Kangmoon SEO, Suwon-si (KR)

(21) Appl. No.: 19/036,387

(22) Filed: Jan. 24, 2025

Related U.S. Application Data
(63) Continuation of application No. PCT/KR2025/000885, filed on Jan. 15, 2025.

(30) Foreign Application Priority Data
Jan. 29, 2024 (KR) 10-2024-0013402

(51) Int. Cl. H05K 1/18; H05K 1/11

(52) U.S. Cl. CPC H05K 1/181; H05K 1/11; H05K 2201/10128

(57) ABSTRACT

A printed circuit board is provided. The printed circuit board includes: at least one mounting hole, a first electronic component module including a first substrate and a plurality of first electronic components mounted in a row and spaced apart from each other on the first substrate, and a second electronic component module including a second substrate and a plurality of second electronic components mounted in a row and spaced apart from each other on the second substrate. The first electronic component module and the second electronic component module are disposed such that the plurality of first components and the plurality of second components are disposed to be interleaved with) each other within the at least one mounting hole.

### CROSS-REFERENCE TO RELATED APPLICATIONS

This application is a continuation of International Application No. PCT/KR2025/000885 designating the United States, filed on Jan. 15, 2025, in the Korean Intellectual Property Receiving Office and claiming priority to Korean Patent Application No. 10-2024-0013402, filed on Jan. 29, 2024, in the Korean Intellectual Property Office, the disclosures of each of which are incorporated by reference herein in their entireties.

### BACKGROUND

### Field

The disclosure relates to a printed circuit board and an electronic device including the same.

### Description of Related Art

When mounting a dual in-line package (DIP)-type electronic component on a printed circuit board, a through hole is formed on the mounting surface of the printed circuit board, and a lead wire of the electronic component is inserted into the through hole and soldered. Recently, as switching mode power supply (SMPS) has become slimmer, there is an increasing demand for a leadless printed circuit board that does not include any lead wire. Accordingly, SMPS is configured without a lead wire by replacing a DIP-type electronic component with a surface mount device (SMD)-type electronic component. Among the parts that can be changed to SMD type electronic components, electrolytic capacitors (EL-capacitors) can be replaced with tantalum capacitors, but since they are not used for general industrial purposes, they are costly, which leads to an overall increase in the price of SMPS.

### SUMMARY

A printed circuit board according to an example embodiment may include: at least one mounting hole, a first electronic component module including a first substrate and a plurality of first electronic components mounted in a row spaced apart on the first substrate, and a second electronic component module including a second substrate and a plurality of second electronic components mounted in a row spaced apart on the second substrate, wherein the first electronic component module and the second electronic component module are disposed such that the plurality of first components and the plurality of second components are disposed to intersect (e.g., be interleaved with) each other within the at least one mounting hole.

The first electronic component module may have the plurality of first electronic components disposed parallel to one side of the printed circuit board. The second electronic component module may have a plurality of second electronic components disposed in parallel to one side of the printed circuit board.

The plurality of first electronic components and the plurality of second electronic components may be alternately disposed one by one.

At least one first electronic component among the plurality of first electronic components may be attached to the second substrate by an adhesive.

At least one second electronic component among the plurality of second electronic components may be attached to the first substrate by an adhesive.

The first substrate may include a plurality of first insertion holes into which leading ends of the plurality of second electronic components are inserted. The second substrate may include a plurality of second insertion holes into which leading ends of the plurality of first electronic components are inserted.

The first substrate includes a plurality of first fixing grooves in which the leading ends of the plurality of second electronic components are mounted. The second substrate may include a plurality of second fixing grooves in which the leading ends of the plurality of first electronic components are mounted.

The leading ends of the plurality of first electronic components may be press-coupled to the plurality of second fixing grooves. The leading ends of the plurality of first electronic components may be press-coupled to the plurality of second fixing grooves.

The printed circuit board may further include an additional mounting hole and a third electronic component module and a fourth electronic component module disposed to intersect each other in the additional mounting hole in a direction different from the first electronic component module and the second electronic component module.

The printed circuit board may further include a third electronic component module comprising a third substrate and a fourth electronic component module comprising a fourth substrate disposed to intersect each other in the additional mounting hole in a direction same as the first electronic component module and the second electronic component module.

One end and the other end of the first substrate and one end and the other end of the second substrate may include a plurality of conductive metal terminals for soldering the first substrate and the second substrate to the printed circuit board.

Each of the plurality of first electronic components and the plurality of second electronic components may include a DIP-type or SMD-type capacitor.

An electronic device according to an example embodiment may include: a housing, a display disposed in the housing, and a printed circuit board disposed between the display and the housing and including at least one processor, comprising processing circuitry, individually and/or collectively, configured to control an operation of the display. The printed circuit board includes: at least one mounting hole, a first electronic component module including a first substrate and a plurality of first electronic components mounted in a row spaced apart on the first substrate, and a second electronic component module including a second substrate and a plurality of second electronic components mounted in a row spaced apart on the second substrate. The first electronic component module and the second electronic component module are disposed such that the plurality of first components and the plurality of second components are disposed to intersect each other within the at least one mounting hole.

The first electronic component module may have the plurality of first electronic components disposed parallel to one side of the printed circuit board. The second electronic component module may have the plurality of second electronic components disposed in parallel to one side of the printed circuit board. The plurality of first electronic components and the plurality of second electronic components may be alternately disposed one by one.

At least one first electronic component among the plurality of first electronic components may attached to the second substrate by an adhesive. At least one second electronic component among the plurality of second electronic components may be attached to the first substrate by an adhesive.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example configuration of an electronic device according to various embodiments;

FIG. 2 is an exploded perspective view illustrating an electronic device according to various embodiments;

FIG. 3 is a perspective view illustrating a portion of a printed circuit board of an electronic device according to various embodiments;

FIG. 4 is a diagram illustrating an example in which a pair of electronic component modules are disposed in a direction intersecting each other according to various embodiments;

FIG. 5 is a diagram illustrating an enlarged view of a plurality of electronic component modules mounted on a printed circuit board of an electronic device according to various embodiments;

FIG. 6 is a perspective view illustrating an electronic component module mounted on a printed circuit board of an electronic device according to various embodiments;

FIG. 7 is an exploded perspective view illustrating an example in which an electronic component module includes a dual in-line package (DIP)-type capacitor according to various embodiments;

FIG. 8 is an exploded perspective view illustrating an example in which an electronic component module includes a surface mount device (SMD)-type capacitor according to various embodiments;

FIG. 9 is a diagram illustrating a comparative example in which a plurality of electronic component modules are individually disposed in parallel;

FIG. 10 is a diagram illustrating an example in which a plurality of electronic component modules are disposed in pairs in a direction intersecting each other according to various embodiments;

FIG. 11 is a diagram illustrating an example in which a plurality of electronic component modules are disposed in a horizontal direction and a vertical direction according to various embodiments;

FIG. 12 is a diagram illustrating an example in which a pair of electronic component modules are disposed in a direction intersecting each other according to various embodiments;

FIG. 13 is a diagram illustrating a substrate of an electronic component module illustrated in FIG. 12 according to various embodiments;

FIG. 14 is a diagram illustrating an example in which a pair of electronic component modules are disposed in a direction intersecting each other according to various embodiments; and

FIG. 15 is a diagram illustrating a substrate of an electronic component module illustrated in FIG. 14 according to various embodiments.

### DETAILED DESCRIPTION

The various example embodiments described in this disclosure and the configurations shown in the drawings are merely example embodiments, and there may be various modifications that can replace the various embodiments and drawings of the disclosure at the time of filing of this application.

In addition, the same reference numerals or symbols shown in each drawing of this disclosure indicate parts or components that perform substantially the same function.

Further, the terms used in this disclosure are used to describe various example embodiments, and are not intended to limit and/or restrict the disclosure. Singular expressions include plural expressions unless the context clearly dictates otherwise. In this disclosure, terms such as “comprise” or “have” are intended to designate the presence of features, numbers, steps, operations, components, parts, or combinations thereof described in the disclosure, but are not intended to exclude in advance the possibility of the presence or addition of various other features, numbers, steps, operations, components, parts, or combinations thereof.

In addition, terms including ordinal numbers such as “first”, “second”, etc. used in this disclosure may be used to describe various components, but the components are not limited by the terms, and the above terms are used simply for the purpose of distinguishing one component from another. For example, a first component may be referred to as a second component, and similarly, the second component may be referred to as a first component without departing from the scope of the present disclosure. The term “and/or” includes a combination of a plurality of related items described herein or any item of a plurality of related items described herein.

The terms “front end”, “rear end”, “upper portion”, “lower portion”, “front”, “rear”, “upper surface”, “lower surface”, “upper end”, “lower end”, “one end”, “the other end”, “left side”, “right side”, etc. used in the present disclosure are defined with reference to the drawings, and the shape and location of each component are not limited by these terms.

When the expression “at least one” among a plurality of components used in the present disclosure appears, the expression refers not only to all of the plurality of components, but also to each one or a combination thereof excluding the rest of the plurality of components.

Hereinafter, an electronic device according to various embodiments will be described in greater detail with reference to accompanying drawings.

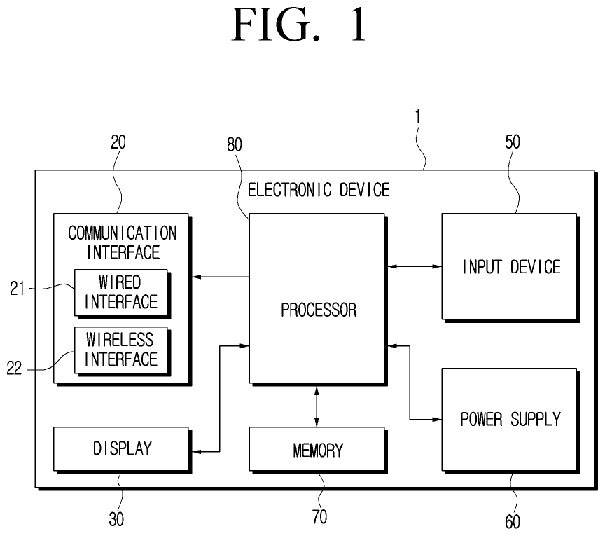

FIG. 1 is a block diagram illustrating an example configuration of an electronic device according to various embodiments.

Referring to FIG. 1, an electronic device 1 may be implemented, for example, as a display device. However, the electronic device 1 according to the present disclosure is simply an example of various implementations of the electronic device 1.

The electronic device 1 is not limited in type, and may be implemented as various types of devices such as, for example, a display device (e.g., TV, monitor, digital signage, electronic blackboard, electronic picture frame, video wall, etc.), an image processing device (e.g., set-top box, optical media playback device, etc.), an information processing device (e.g., computer main body, laptop computer, etc.), a mobile device (e.g., smartphone, tablet device, portable multimedia playback device, etc.), a wearable device, household appliance (e.g., refrigerator, washing machine, air conditioner, dishwasher, etc.), or the like.

The electronic device 1 may include a communication interface 20 including various communication circuitry. The communication interface 20 may include interface circuitry for the electronic device 1 to perform communication with various kinds of devices and servers including external devices, and also to transmit and receive data. The communication interface 20 may include at least one of various wired interfaces 21 for wired communication connections and various wireless interfaces 22 for wireless communication connections.

The wired interface 21 includes a connector or a port to which a cable of a predefined transmission specification is connected. For example, the wired interface 21 may include a port to which a terrestrial or satellite broadcasting antenna is connected or a cable for cable broadcasting is connected in order to receive a broadcasting signal. The wired interface 21 may include a port to which cables of various wired transmission standards such as high definition multimedia interface (HDMI), display port (DP), digital visual interface (DVI), component, composite, S-Video, and Thunderbolt are connected in order to connect to various image processing devices. The wired interface 21 may include a port of a USB standard to connect to a universal serial bus (USB) device. The wired interface 21 may include an optical port to which an optical cable is connected. The wired interface 21 may include an audio input port to which an external microphone is connected, and an audio output port to which a headset, earphones, external speakers, or the like are connected. The wired interface 21 may include an Ethernet port for connecting to a gateway, router, hub, or the like in order to connect to a wide area network.

The wireless interface 22 may include a two-way communication circuit that includes at least one of components such as a communication module, a communication chip, etc. corresponding to various types of wireless communication protocols. For example, the wireless interface 22 may include a Wi-Fi communication chip that performs wireless communication with an access point (AP) according to a Wi-Fi method, a communication chip that performs wireless communication such as Bluetooth, Zigbee, Z-Wave, WirelessHD, WiGig, NFC, etc., an IR module for IR communication, a mobile communication chip that performs mobile communication with a mobile device, etc.

The electronic device 1 may include a display 30 capable of displaying an image on a screen. The display 30 may have a light-receiving structure such as a liquid crystal type, or a self-lighting structure including a plurality of light-emitting elements such as organic light-emitting diodes (OLEDs), Mini LEDs, or Micro LEDs. When the display 30 is a liquid crystal-type display, it may include a liquid crystal display panel, a backlight unit that supplies light, and a panel driving substrate that drives the liquid crystal of the liquid crystal display panel. When the display 30 includes a self-luminous structure, it may include a substrate on which the driving circuitry is disposed and a plurality of pixels disposed at a constant pitch on the substrate. In this case, a pixel may include a plurality of sub-pixels. The plurality of sub-pixels may be a plurality of light-emitting elements that emit light in different wavelength bands. One sub-pixel may be a single light-emitting element (e.g., OLED, Mini LED, or Micro LED).

The electronic device 1 may include an input device 50 including various input circuitry. The input device 50 may include various types of user input interface-related circuitry disposed to be operated by a user to perform a user input. The input device 50 can be configured in various ways depending on the type of electronic device 1. For example, the input device 50 may be a mechanical or electronic button on the electronic device 1, a touchpad, a sensor, a camera, a touchscreen, or a remote controller separate from the main body of the electronic device 1.

The electronic device 1 may include a power supply 60. The power supply 60 may adjust the power characteristics of an input external power source to correspond to each component of the electronic device 1 and transmit the power to the corresponding components. For example, the power supply 60 may convert alternating current (AC) power input from an external power source to direct current (DC) power, and output power that is adjusted to a current or voltage suitable for each component of the electronic device 1. To this end, the power supply 60 may include a switched mode power supply (SMPS).

The electronic device 1 may include memory 70. The memory 70 stores digitized data. The memory 70 includes non-volatile storage that can retain data regardless of whether power is supplied, and volatile memory that is loaded with data to be processed by a processor 80 and cannot retain data unless power is provided. The storage may include flash-memory, hard-disk drive (HDD), solid-state drive (SSD) read only memory (ROM), and the memory may include a buffer, random access memory (RAM), and the like.

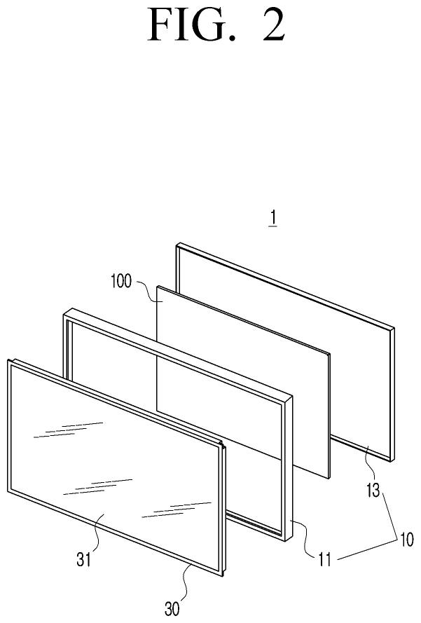

The electronic device 1 may include a processor 80 including various processing circuitry. The processor 80 may include various hardware processors which are implemented as CPUs, chipsets, buffers, circuits, etc. mounted on a printed circuit board 100 (see FIG. 2), and may be implemented as a system on chip (SoC), depending on the design method.

The processor 80 may be implemented as a digital signal processor (DSP) for processing digital signals, a microprocessor, a graphics processing unit (GPU), an artificial intelligence (AI) processor, a neural processing unit (NPU), or a time controller (TCON). However, the processor 80 is not limited thereto, and the processor 80 may include one or more of a central processing unit (CPU), a micro controller unit (MCU), a micro processing unit (MPU), a controller, an application processor (AP) or a communication processor (CP), and an ARM processor, or may be defined as the corresponding term. The processor 80 may be implemented as a system on chip (SoC) with embedded processing algorithms, a large scale integration (LSI), or in the form of an application specific integrated circuit (ASIC) or a field programmable gate array (FPGA). The processor 80 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The processor 80 may drive an operating system or application program to control hardware or software components connected to the processor 80, and may perform various data processing and computations. In addition, the processor 80 may load instructions or data received from at least one of the other components into volatile memory for processing, and may store various data in non-volatile memory.

When the electronic device 1 is implemented as a display device, the processor 80 may include modules corresponding to various processes, such as a de-multiplexer, a decoder, a scaler, an audio digital signal processor (DSP), an amplifier, and the like,. Here, some or all of these modules may be implemented as an SoC. For example, modules related to image processing, such as a de-multiplexer, a decoder, and a scaler, may be implemented as image processing SoC, while an audio DSP may be implemented as a chipset separate from the SoC.

FIG. 2 is an exploded perspective view illustrating an electronic device according to various embodiments.

The electronic device 1 according to various embodiments may be a display device, as shown in FIG. 2. The electronic device 1 may include a housing 10 forming an exterior, a display 30, and the printed circuit board 100.

The housing 10 may include an edge frame 11 forming a side surface of the electronic device 1, and a rear chassis 13 forming a rear surface of the electronic device 1. The edge frame 11 may have a frame shape with an open front surface and an open rear surface. The rear chassis 13 may be coupled to the edge frame 11. The rear chassis 13 may be coupled to the open rear surface of the edge frame 11 so as to form an exterior of the electronic device 1 together with the edge frame 11.

The display 30 may be disposed inside the housing 10. The display 30 may be provided with a screen 31 on which still images and moving images are displayed. The display 30 may display various images on the screen according to an image signal input from the outside. The display 30 may include a self-luminous display panel that generates an image by having multiple pixels generate light on their own, or a non-luminous display panel that generates an image by having multiple pixels reflect/transmit/block light.

The display panel may be provided with a display driver IC. The display driver IC may include an interface module, buffer memory, an image processing module, or a mapping module. The display driver IC may receive, for example, image information including image data or an image control signal corresponding to a command for controlling the image data, from another component of the electronic device 1 through an interface module. For example, the image information may be received from the processor 80 (e.g., a main processor (e.g., an application processor) or an auxiliary processor (e.g., a graphics processing unit) that operates independently of the function of the main processor.

The display driver IC may perform communication with a sensor module via the interface module. In addition, the display driver IC may store at least a portion of the received image information in buffer memory, for example, on a frame-by-frame basis. The image processing module may, for example, perform pre-processing or post-processing (e.g., resolution, brightness, or size adjustment) of at least a portion of the image data based on characteristics of the image data or characteristics of the display panel. The mapping module may generate a voltage value or a current value corresponding to the pre-processed or post-processed image data via the image processing module. According to an embodiment, the generation of the voltage value or current value may be performed, for example, based at least in part on properties of the pixels of the display panel (e.g., arrangement of pixels (RGB stripe or pentile structure) or size of each of the sub-pixels). At least some of the pixels of the display panel may be driven, for example, based at least in part on the voltage value or current value, such that visual information (e.g., text, images, or icons) corresponding to the image data may be displayed via the display 30.

The display driver IC may transmit a driving signal (e.g., a driver driving signal, a gate driving signal, etc.) to the display based on the image information received from the processor 80. The display driver IC may display an image based on an image signal received from the processor 80. In one example, the display driver IC may generate driving signals of a plurality of sub-pixels based on the image signal received from the processor 80, and may display the image by controlling light emission of the plurality of sub-pixels based on the driving signal.

The printed circuit board 100 may be disposed between the housing 10 and the display 30. The printed circuit board 100 may be detachably coupled to the rear chassis 13 by a plurality of screws. The printed circuit board 100 may be used as a main board that is different from a display substrate included in the display 30.

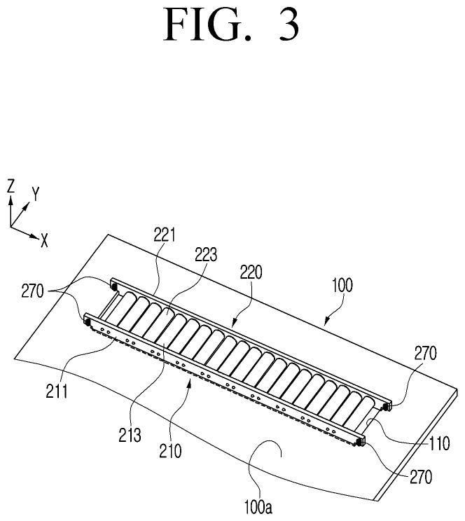

The printed circuit board 100 may be provided with an insulating layer and a mounting layer on both sides (front and rear) of the insulating layer. The insulating layer may be a prepreg. For example, the insulating layer may be a composite of reinforcing fibers infiltrated with a matrix resin. The mounting layer may include a metal layer or metal wiring for electrical connection with a plurality of electronic components or electronic component modules 200, 300 (see FIG. 3). For example, the mounting layer may be formed of copper. The mounting layer may have electrode wires or electrode pads of the processor 80, the plurality of electronic components and/or the electronic component modules 200, 300 electrically connected thereto. The mounting layer may be provided with a solder mask to prevent/reduce corrosion, and a silk screen to display characters or symbols.

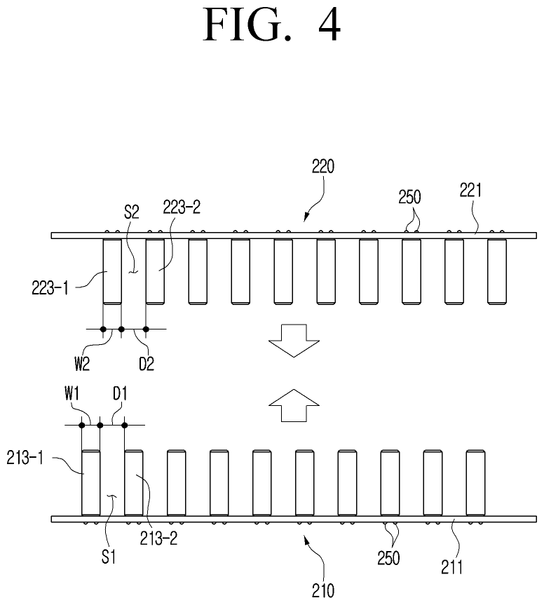

FIG. 3 is a perspective view illustrating a portion of a printed circuit board of an electronic device according to various embodiments. FIG. 4 is a diagram illustrating an example in which a pair of electronic component modules are disposed in a direction intersecting each other according to various embodiments.

Referring to FIG. 3, the printed circuit board 100 may be provided with a mounting holes 110 into which a first electronic component module 210 and a second electronic component module 220 may be mounted. The mounting holes 110 may have a length along the X-axis direction in FIG. 3 and a width along the Y-axis direction in FIG. 3.

For example, the length of the mounting holes 110 may be approximately shorter than the length of the first electronic component module 210 and the second electronic component module 220. In this case, a plurality of first electronic components 213 mounted on the first electronic component module 210 and a plurality of second electronic components 223 mounted on the second electronic component module 220 may be inserted, and both ends of a first substrate 211 of the first electronic component module 210 and both ends of a second substrate 221 of the second electronic component module 220 may be respectively mounted around the mounting holes 110. The width of the mounting holes 110 may be larger than the widths of the first electronic component module 210 and the second electronic component module 220 when the first electronic component module 210 and the second electronic component module 220 are disposed to intersect or be interleaved each other. In this case, a portion of the first substrate 211 of the first electronic component module 210 and a portion of the second substrate 221 of the second electronic component module 220 may be inserted into the mounting holes 110. In this description, the terms “intersect” or “intersecting” may be used interchangeably with the terms “interleaved” or “interleaving”.

The first electronic component module 210 and the second electronic component module 220 mounted on the printed circuit board 100 may be disposed to intersect each other. This may refer, for example, to the plurality of second electronic components 223 of the second electronic component module 220 being disposed one by one between the plurality of first electronic components 213 of the first electronic component module 210. In this case, the plurality of first electronic components 213 of the first electronic component module 210 and the plurality of second electronic components 223 of the second electronic component module 220 inserted into the mounting holes 110 may be disposed approximately parallel to the printed circuit board 100.

Referring to FIG. 4, one second electronic component 223-1 may be inserted into a first space S1 between a pair of adjacent first electronic components 213-1, 213-2. In addition, one first electronic component 213-2 may be inserted into a second space S2 between a pair of adjacent second electronic components 223-1, 223-2. Accordingly, when the first electronic component module 210 and the second electronic component module 220 are mounted in the mounting holes 110 of the printed circuit board 100 so as to intersect each other, the first plurality of first electronic components 213 and the second plurality of second electronic components 223 may be disposed alternately one by one along the X-axis direction as shown in FIG. 3.

In this case, a first interval D1 of the pair of first electronic components 213-1, 213-2 may be larger than a first width W1 of the first electronic component 213-1. In addition, a second interval D2 of the pair of second electronic components 223-1, 223-2 may be larger than a second width W2 of the second electronic component 223-1. For example, the first interval D1 may be approximately 1.1 to 1.2 times the first width W1. The second interval D2 may be approximately 1.1 to 1.2 times the second width W2. Accordingly, when the plurality of second electronic components 223 are inserted between the plurality of first electronic components 213, the plurality of first electronic components 213 and the plurality of second electronic components 223 may not interfere with each other.

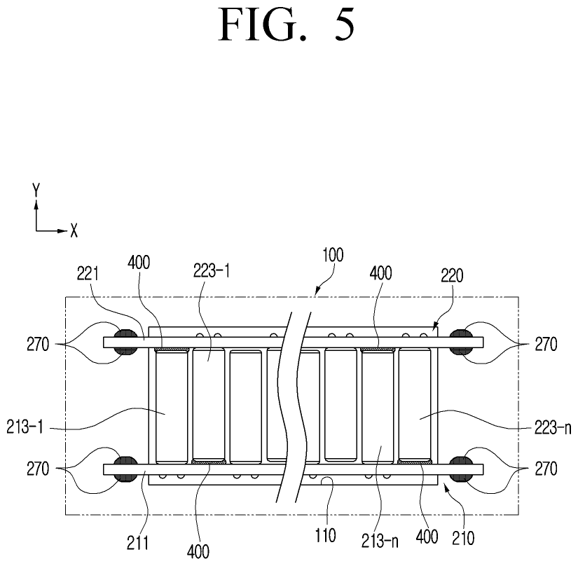

FIG. 5 is a diagram illustrating an enlarged view of a plurality of electronic component modules mounted on a printed circuit board of an electronic device according to various embodiments.

Referring to FIG. 5, the first electronic component module 210 may be soldered to the printed circuit board 100 by solder 270 on both sides of one end and both sides of the other end. Accordingly, the first electronic component module 210 and the second electronic component module 220 may be physically fixed to the printed circuit board 100. In this case, the first substrate 211 of the first electronic component module 210 and the second substrate 221 of the second electronic component module 220 may be mounted approximately perpendicular to a mounting surface 100a of the printed circuit board 100. Accordingly, the first electronic component module 210 and the second electronic component module 220 may be mounted on the printed circuit board 100 so as to have a minimum/relatively small height from the mounting surface 100a of the printed circuit board 100.

The first electronic component module 210 and the second electronic component module 220 may be attached to each other by an adhesive 400. In this case, the adhesive 400 may be applied between at least one of the plurality of first electronic components 213 and the second substrate 221, and between at least one of the second electronic components 223 and the first substrate 211.

For example, as shown in FIG. 5, the adhesive 400 may be applied between two first electronic components 213-1, 213-n located at the outermost side of the plurality of first electronic components of the first electronic component module 210 and the second substrate 221 of the electronic component module 220. In addition, the adhesive 400 may be applied between two second electronic components 223-1, 223-n located at the outermost side of the plurality of second electronic components of the second electronic component module 220 and the first substrate 211 of the first electronic component module 210. Accordingly, the first electronic component module 210 and the second electronic component module 220 may be firmly fixed to each other via the adhesive 400.

Hereinafter, the first electronics module 210 will be described with reference to the drawings. The second electronic component module 220 has substantially the same structure as the first electronic component module 210 and may not be described in detail.

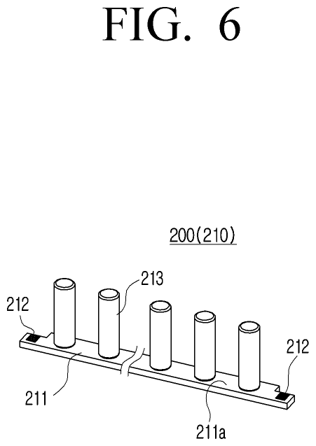

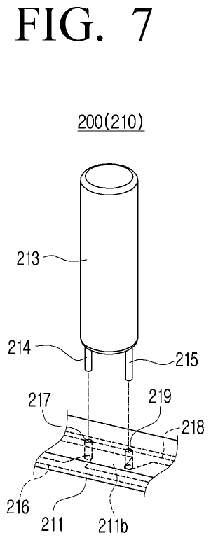

FIG. 6 is a perspective view illustrating an electronic component module mounted on a printed circuit board of an electronic device according to various embodiments. FIG. 7 is an exploded perspective view illustrating an example in which an electronic component module includes a dual in-line package (DIP)-type capacitor according to various embodiments.

Referring to FIG. 6, the first electronic component module 210 may include the first substrate 211, and the plurality of first electronic components 213 disposed in one column (or one row) with a first interval D1 on a first surface 211a of the first substrate 211.

The first substrate 211 may be provided with a plurality of conductive metal terminals 212 on both sides of the first surface 211a and on both sides of a second surface 211b opposite to the first surface 211a. The plurality of conductive metal terminals 212 may be coated with the solder 270 and may be electrically and physically connected to the mounting surface 110a (see FIG. 3A) of the printed circuit board. One of the conductive metal terminals 212 may be electrically connected to a first wiring 216 formed on the second surface 211b of the first substrate 211. Another one of the conductive metal terminals 212 may be electrically connected to a second wiring 218 formed on the second surface 211b of the first substrate 211.

Referring to FIG. 7, the first electronic component 213 may be a capacitor. For example, the first electronic component 213 may be a DIP-type capacitor provided with a first lead wire 214 and a second lead wire 215 at the lower end. The first lead wire 214 and the second lead wire 215 may be inserted into a first through hole 217 and a second through hole 219 provided in the first substrate 211.

The first lead wire 214 may be electrically connected to the first wiring 216 by solder 250 (see FIG. 4). The second lead wire 215 may be electrically connected to the second wiring 218 by the solder 250. The first wiring 216 and the second wiring 218 may be formed on the second surface 211b of the first substrate 211 along the length direction of the first substrate 211 at regular intervals.

The first electronic component 213 is not limited to a DIP-type capacitor and may be an SMD-type capacitor.

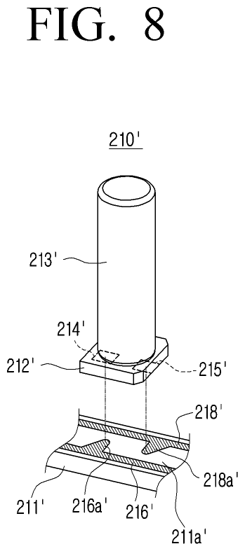

FIG. 8 is an exploded perspective view illustrating an example in which an electronic component module includes a surface mount device (SMD)-type capacitor according to various embodiments.

As shown in FIG. 8, a plurality of first electronic components 213′ included in a first electronic component module 210′ may all be SMD-type capacitors. In this case, a plurality of through holes in a first substrate 211′ may be omitted.

The first electronic components 213′ may have a small substrate 212′ provided at the lower end, and a first terminal 214′ and a second terminal 215′ may be provided on the lower surface of the small substrate 212′. The first substrate 211a′ may have with a first wiring 216′ and a second wiring 218′ formed spaced apart along the length direction of the first substrate 211a′.

The first terminal 214′ of the first electronic component 213′ may be soldered to a first pad 216a′ extended on the first wiring 216′. The second terminal 215′ of the first electronic component 213′ may be soldered to a second pad 218a′ extended on the second wiring 218′.

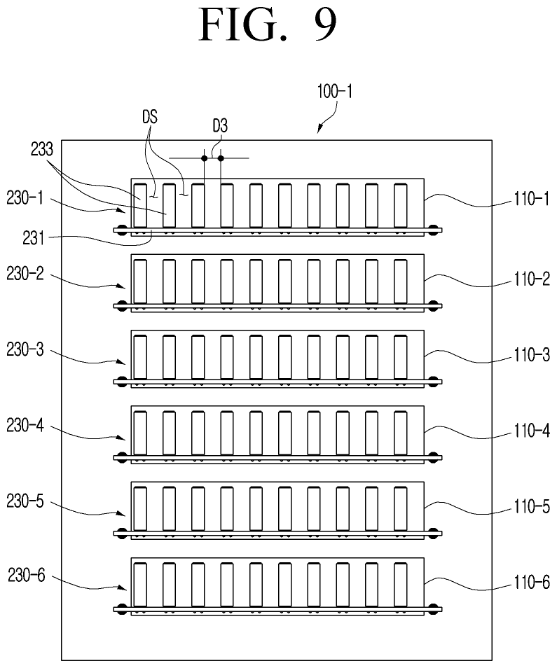

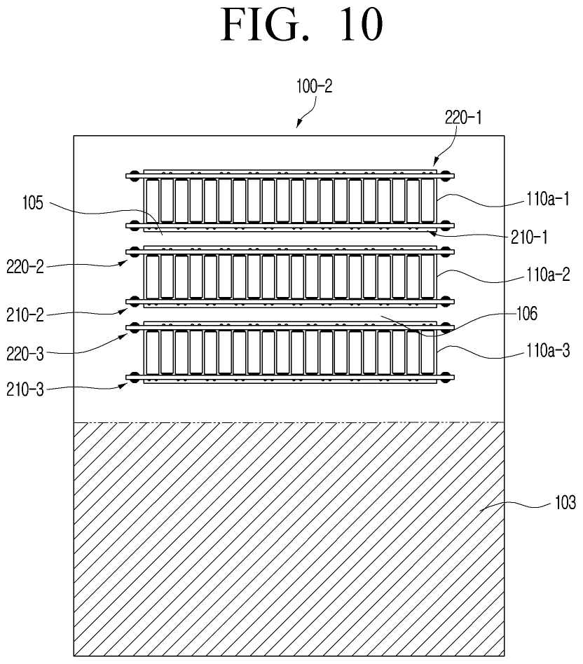

FIG. 9 is a diagram illustrating a comparative example in which a plurality of electronic component modules are individually disposed in parallel. FIG. 10 is a diagram illustrating an example in which a plurality of electronic component modules are disposed in pairs in a direction intersecting each other according to various embodiments.

Referring to FIG. 9, a printed circuit board 100-1 according to a comparative example has six electronic component modules 230-1, 230-2, 230-3, 230-4, 230-5, 230-6 mounted in six mounting holes 110-1, 110-2, 110-3, 110-4, 110-5, 110-6, respectively. As such, the printed circuit board 100-1 according to the comparative example is disposed such that the electronic component modules correspond to the mounting holes on a one-to-one basis.

As such, when one electronic component module 230-1 is mounted in one mounting hole 110-1, there is a dead space (DS) in the mounting hole 110-1. Due to the dead space (DS) in the six mounting holes 110-1, 110-2, 110-3, 110-4, 110-5, 110-6, it is difficult to reduce the size of the printed circuit board 100-1. The dead space DS is caused by an interval D3 between adjacent electronic components 233 mounted on the substrate 231 of the electronic component module 230-1.

The plurality of electronic components 233 are gripped by fingers provided on a robot arm and go through a process of being automatically mounted on the substrate 231. When the fingers grip the electronic components and mount them on the substrate 231, a certain interval D3 must be maintained between the adjacent electronic components 233 to prevent or avoid the fingers from interfering with the electronic components mounted on the substrate 231 previously. Accordingly, it is difficult to reduce the interval D3 between the plurality of electronic components 233 of the electronic component module 230-1.

The printed circuit board of the present disclosure may use the dead space (DS) by disposing the plurality of electronic component modules differently from the comparative example.

Referring to FIG. 10, a printed circuit board 100-2 according to various embodiments may be provided with a plurality of mounting holes spaced approximately parallel to each other. The plurality of mounting holes may be provided as first, second, and third mounting holes 110a-1, 110a-2, 110a-3.

In this case, the printed circuit board 100-1 may be configured such that a first electronic component module 210-1 and a second electronic component module 220-1 are mounted so as to intersect each other in the first, second, and third mounting holes 110a-1, 110a-2, 110a-3, a third electronic component module 210-2 and a fourth electronic component module 220-2 are mounted so as to intersect each other, and a fifth electronic component module 210-3 and a sixth electronic component module 220-3 are mounted so as to intersect each other.

As such, the printed circuit board 100-2 according to various embodiments may have three fewer mounting holes than the printed circuit board 100-1 of the comparative example, but may have the same six electronic component modules as the printed circuit board 100-1 of the comparative example.

Accordingly, the printed circuit board 100-2 according to various embodiments may reduce the area on which the electronic component modules are mounted by approximately 40-50% compared to the comparative example of FIG. 9. The printed circuit board 100-2 may be reduced in size by the amount of a free area 103. In addition, the free area 103 of the printed circuit board 100-2 may be used as an area for mounting electronic components, etc. to implement various additional functions of the electronic device 1.

The printed circuit board 100-2 may omit a first portion 105 of the printed circuit board 100-2 disposed between the first and second mounting holes 110a-1, 110a-2 and a second portion 106 of the printed circuit board 100-2 disposed between the second and third mounting holes 110a-2, 110a-3. In this case, the printed circuit board 100-2 may have six electronic component modules 210-1, 210-2, 210-3, 220-1, 220-2, 220-3 installed in one mounting hole.

The third electronic component module 210-2 and the fourth electronic component module 220-2, which are disposed to intersect each other, may be disposed adjacent to the first electronic component module 210-1, and the fifth electronic component module 210-3 and the fourth electronic component module 220-3, which are disposed to intersect each other, may be disposed adjacent to the third electronic component module 210-2. In this case, the size of the printed circuit board 100-2 may be further reduced by the size of the first portion 105 and the second portion 106.

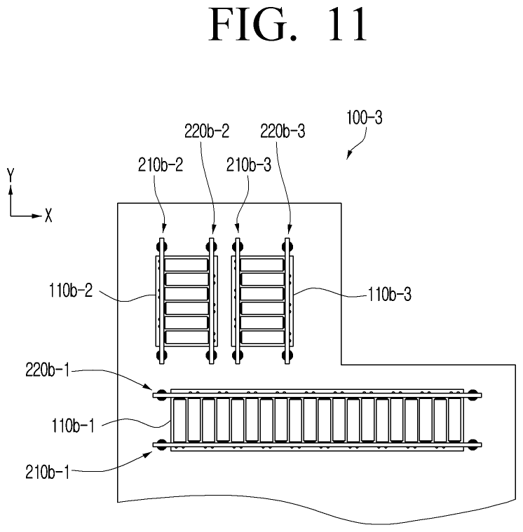

FIG. 11 is a diagram illustrating an example in which a plurality of electronic component modules are disposed in a horizontal direction and a vertical direction according to various embodiments.

Referring to FIG. 11, a printed circuit board 100-3 according to various embodiments may have a plurality of electronic component modules disposed in various directions depending on its shape.

For example, the printed circuit board 100-3 may have a shape in which the upper right side of the printed circuit board 100-3 is cut. The printed circuit board 100-3 may have a first electronic component module 210b-1 and a second electronic component module 220b-1 disposed to intersect each other along a first direction (e.g., the X-axis direction of FIG. 11) on the lower portion of the printed circuit board 100-3 having a width wider than the upper portion of the printed circuit board 100-3. The printed circuit board 100-3 may have a third electronic component module 210b-2 and a fourth electronic component module 220b-2 disposed to intersect each other along a second direction (e.g., the Y-axis direction of FIG. 11) on the upper left side of the printed circuit board 100-3, and a fifth electronic component module 210b-3 and a sixth electronic component module 220b-3 disposed to intersect each other along the second direction.

Each of the lengths of the third electronic component module 210b-2, the fourth electronic component module 220b-2, the fifth electronic component module 210b-3, and the sixth electronic component module 220b-3 may be shorter than the lengths of the first electronic component module 210b-1 and the second electronic component module 220b-1. Accordingly, the length of a first mounting hole 110b-1 may be formed longer than the lengths of second and third mounting holes 110b-2, 110b-3.

As such, the printed circuit board 100-3 may apply various arrangement directions and lengths of a plurality of electronic component modules by considering its shape, thereby improving ease of manufacturing.

The pair of electronic component modules 210, 220 disposed to intersect each other as shown in FIG. 5 may be firmly fixed to each other using an adhesive 400.

Hereinafter, a printed circuit device in which a pair of electronic component modules can be firmly fixed to each other without using the adhesive 400 will be described with reference to the drawings.

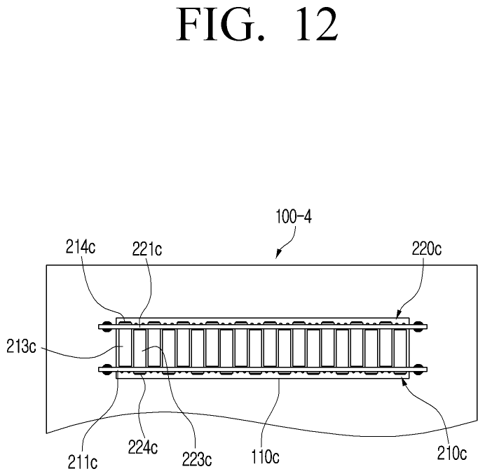

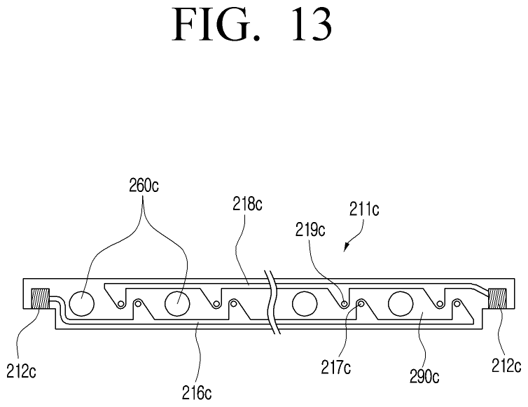

FIG. 12 is a diagram illustrating an example in which a pair of electronic component modules are disposed in a direction intersecting each other according to various embodiments. FIG. 13 is a diagram illustrating a substrate of an electronic component module illustrated in FIG. 12 according to various embodiments.

Referring to FIG. 12, a plurality of first electronic components 213c of a first electronic component module 210c may be mounted in a mounting hole 110c of a printed circuit board 100-4 so as to intersect each other. In this case, the plurality of first electronic components 213c of the first electronic component module 210c may have a leading end 214c that each penetrates a second substrate 221c of a second electronic component module 220c. A plurality of second electronic components 223c of the second electronic component module 220c may each have a leading end 224c that each penetrates a first substrate 211c of a first electronic component module 210c.

Referring to FIG. 13, the first substrate 211c of the first electronic component module 210c may have a first wiring 216c and a second wiring 218c disposed spaced apart from each other on a second surface 290c along the length direction of the first substrate 211c. The first surface of the first substrate 211c may be formed on an opposite side of the second surface 290c and may be mounted with the plurality of first electronic components 213c. The first wiring 216c may be connected to a plurality of first through holes 217c, and the second wiring 218c may be connected to a plurality of second through holes 219c. The first wiring 216c may be electrically connected to one of conductive metal terminals 212c, and the second wiring 218c may be electrically connected to another one of the conductive metal terminals 212c.

The first substrate 211c of the first electronic component module 210c may be provided with a plurality of first insertion holes 260c into which the leading end 224c of the plurality of second electronic components 223c of the second electronic component module 220c is inserted. The plurality of first insertion holes 260c are disposed between the first wiring 216c and the second wiring 218c, and may be disposed along the length direction of the first substrate 211c at a certain interval.

The second substrate 221c of the second electronic component module 220c may be configured substantially the same as the first substrate 211c of the first electronic component module 210c. Accordingly, the second substrate 221c may be provided with a plurality of second insertion holes into which the leading end 214c of the plurality of first electronic components 213c is inserted.

When the first electronic component module 210c and the second electronic component module 220c are disposed with each other, the leading end 224c of the plurality of second electronic components 223c may be inserted into a plurality of first insertion holes 260c provided in the first substrate 211c of the facing first electronic component module 210c, the leading end 214c of the plurality of first electronic components 213c may be inserted into a plurality of second insertion holes provided in the second substrate 221c of the facing second electronic component module 220c.

Accordingly, the first electronic component module 210c and the second electronic component module 220c may be firmly fixed to each other without using the adhesive 400. The printed circuit board 100-4 may omit the process of applying the adhesive 400 among the manufacturing processes, so it is possible to shorten the manufacturing time and reduce material costs.

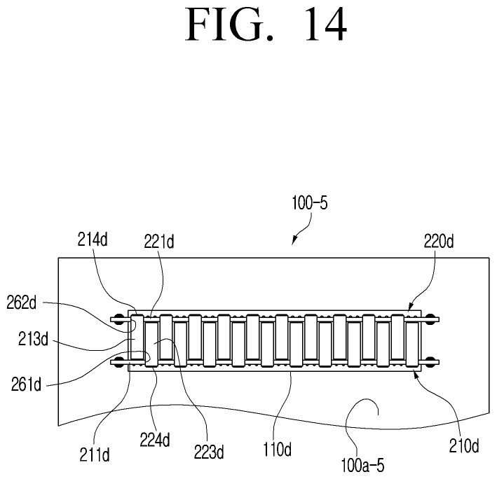

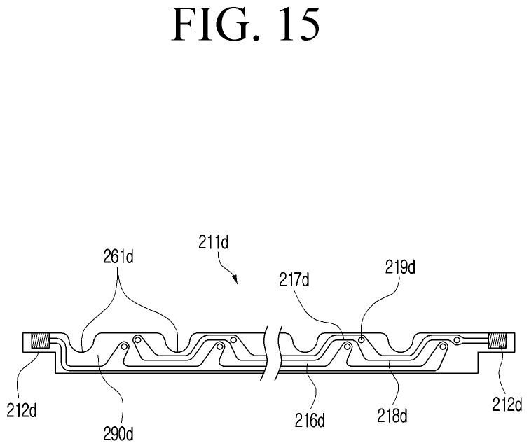

FIG. 14 is a diagram illustrating an example in which a pair of electronic component modules are disposed in a direction intersecting each other according to various embodiments. FIG. 15 is a diagram illustrating a substrate of an electronic component module illustrated in FIG. 14 according to various embodiments.

Referring to FIG. 14, a plurality of first electronic components 213d of a first electronic component module 210d may be mounted so as to intersect each other in a mounting holes 110d of a printed circuit board 100-5. In this case, the plurality of first electronic components 213d of the first electronic component module 210d may each have their leading end 214d inserted into a plurality of first fixing grooves 262d of a second substrate 221d of a second electronic component module 220d. A plurality of second electronic components 223d of a second electronic component module 220d may each have their leading end 224d inserted into a plurality of second fixing grooves 261d of a first substrate 211d of a first electronic component module 210d.

Referring to FIG. 15, the first substrate 211d of the first electronic component module 210d may have a first wiring 216d disposed along the length direction of the first substrate 211d on a second surface 290d. The first surface of the first substrate 211d may be formed on the opposite side of the second surface 290d and the plurality of first electronic elements 213d may be mounted thereon.

A second wiring 218d may be disposed on the second surface 290d along the length direction of the first substrate 211d. In this case, the second wiring 218d may be disposed spaced apart from the plurality of first fixing grooves 261d so as not to interfere with the plurality of first fixing grooves 261d.

The first wiring 216d may be connected to a plurality of first through holes 217d, and the second wiring 218d may be connected to a plurality of second through holes 219d. The first wiring 216d may be electrically connected to one of conductive metal terminals 212d, and the second wiring 218d may be electrically connected to another one of the conductive metal terminals 212d.

The first substrate 211d of the first electronic component module 210d may be provided with the plurality of first fixing grooves 261d in which the leading end 224c of the plurality of second electronic components 223d of the second electronic component module 220d are mounted. The second substrate 221d of the second electronic component module 220d may be configured substantially the same as the first substrate 211d of the first electronic component module 210d. Accordingly, the second substrate 221d may be provided with the plurality of second fixing grooves 262d in which the leading end 214d of the plurality of first electronic components 213d are mounted.

The diameter of the plurality of first fixing grooves 261d may be formed to be somewhat smaller or approximately the same as the diameter of the leading end 224d of the plurality of second electrical components 223d. Accordingly, the leading end 224d of the plurality of second electrical components 223d may be firmly coupled to the plurality of first retaining grooves 261d in a pressed state. Likewise, the diameter of the plurality of second fixing grooves 262d may be formed to be somewhat smaller or substantially the same as the diameter of the leading end 214d of the plurality of first electrical components 213d. Accordingly, the leading end 214d of the plurality of first electrical components 213d may be firmly coupled to the plurality of second fixing grooves 262d in a pressed state.

When the first electronic component module 210d and the second electronic component module 220d are disposed to intersect each other, the leading end 224d of the plurality of second electronic components 223d may be mounted in the plurality of first fixing grooves 261d provided in the first substrate 211d of the facing first electronic component module 210d, and the leading end 214d of the plurality of first electronic components 213d may be inserted into the plurality of second fixing grooves 262d provided in the second substrate 221d of the facing second electronic component module 220d. The plurality of first fixing grooves 261d and the plurality of second fixing grooves 262d may open in the same direction.

When the first electronic element module 210d and the second electronic element module 220d are mounted on the printed circuit board 100-5, the height from a mounting surface 100a-5 of the printed circuit board 100-5 to the top of the first and second electronic element modules 210d, 220d (e.g., the top of the first substrate 211d and the top of the second substrate 221d) can be minimized/reduced.

In addition, the first electronic component module 210d and the second electronic component module 220d may be firmly fixed to each other without using the adhesive 400. The printed circuit board 100-5, like the printed circuit board 100-4 of FIG. 12, may omit the process of applying the adhesive 400 among the manufacturing processes, thereby shortening manufacturing time and reducing material costs.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A printed circuit board comprising:
at least one mounting hole;
a first electronic component module including a first substrate and a plurality of first electronic components mounted in a row and spaced apart from each other on the first substrate; and
a second electronic component module including a second substrate and a plurality of second electronic components mounted in a row and spaced apart from each other on the second substrate,
wherein the first electronic component module and the second electronic component module are disposed such that the plurality of first components and the plurality of second components are disposed to be interleaved with each other within the at least one mounting hole.

2. The printed circuit board as claimed in claim 1, wherein in the first electronic component module, the plurality of first electronic components are disposed parallel on one side of the printed circuit board; and
wherein in the second electronic component module, the plurality of second electronic components are disposed in parallel on one side of the printed circuit board.

3. The printed circuit board as claimed in claim 2, wherein the plurality of first electronic components and the plurality of second electronic components are alternately disposed.

4. The printed circuit board as claimed in claim 3, wherein at least one first electronic component among the plurality of first electronic components is attached to the second substrate by an adhesive.

5. The printed circuit board as claimed in claim 4, wherein at least one second electronic component among the plurality of second electronic components is attached to the first substrate by an adhesive.

6. The printed circuit board as claimed in claim 3, wherein the first substrate includes a plurality of first insertion holes configured to receive leading ends of the plurality of second electronic components; and
wherein the second substrate includes a plurality of second insertion holes configured to receive leading ends of the plurality of first electronic components.

7. The printed circuit board as claimed in claim 3, wherein the first substrate includes a plurality of first fixing grooves configured to mount the leading ends of the plurality of second electronic components; and
wherein the second substrate includes a plurality of second fixing grooves configured to mount the leading ends of the plurality of first electronic components.

8. The printed circuit board as claimed in claim 7, wherein the leading ends of the plurality of first electronic components are press-coupled to the plurality of second fixing grooves; and
wherein the leading ends of the plurality of first electronic components are press-coupled to the plurality of second fixing grooves.

9. The printed circuit board as claimed in claim 1, further comprising:
an additional mounting hole; and
a third electronic component module comprising a third substrate and a fourth electronic component module comprising a fourth substrate disposed to be interleaved with each other in the additional mounting hole in a direction different from the first electronic component module and the second electronic component module.

10. The printed circuit board as claimed in claim 9, further comprising a third electronic component module and a fourth electronic component module disposed to be interleaved with each other in the additional mounting hole in a same direction as the first electronic component module and the second electronic component module.

11. The printed circuit board as claimed in claim 1, wherein one end and an other end of the first substrate and one end and an other end of the second substrate include a plurality of conductive metal terminals configured to be solder the first substrate and the second substrate to the printed circuit board.

12. The printed circuit board as claimed in claim 1, wherein each of the plurality of first electronic components and the plurality of second electronic components includes a dual in-line package (DIP)-type or surface mount device (SMD)-type capacitor.

13. An electronic device, comprising:
a housing:
a display disposed in the housing; and
a printed circuit board disposed between the display and the housing and including at least one processor, configured to control an operation of the display, wherein the printed circuit board comprises:
at least one mounting hole;
a first electronic component module including a first substrate and a plurality of first electronic components mounted in a row and spaced apart from each other on the first substrate; and
a second electronic component module including a second substrate and a plurality of second electronic components mounted in a row and spaced apart from each other on the second substrate,
wherein the first electronic component module and the second electronic component module are disposed such that the plurality of first components and the plurality of second components are disposed to be interleaved with each other within the at least one mounting hole.

14. The electronic device as claimed in claim 13, wherein the first electronic component module has the plurality of first electronic components disposed in parallel with one side of the printed circuit board;
wherein the second electronic component module has the plurality of second electronic components disposed in parallel with one side of the printed circuit board; and
wherein the plurality of first electronic components and the plurality of second electronic components are alternately disposed.

15. The electronic device as claimed in claim 14, wherein at least one first electronic component among the plurality of first electronic components is attached to the second substrate by an adhesive; and
wherein at least one second electronic component among the plurality of second electronic components is attached to the first substrate by an adhesive.
